(19) United States
(12) Patent Application Publication
(10) Pub. No.: US 2006/0069974 A1
(43) Pub. Date: Mar. 30, 2006

(54) One-hot encoded instruction register for boundary scan test compliant devices

(75) Inventors: Thomas Herrmann, Dresden (DE); Frank Barth, Radebeul (DE)

Correspondence Address: MEYERTONS, HOOD, KIVLIN, KOWERT & GOETZEL, P.C., P.O. BOX 398, AUSTIN, TX, 78767-0398, US

(73) Assignee: Advanced Micro Devices, Inc.

(21) Appl. No.: 11/011,398

(22) Filed: Dec. 14, 2004

(30) Foreign Application Priority Data
Sep. 30, 2004 (DE) 10 2004 047 632.2

(51) Int. Cl. G01R 31/28

(52) U.S. Cl. 714/727

(57) ABSTRACT

An integrated circuit chip operable in a plurality of Boundary Scan test modes in which at least a part of the circuitry comprised in the integrated circuit chip is tested is provided. The integrated circuit chip comprises a Boundary Scan register and an instruction register. The Boundary Scan register is arranged to perform a test on the tested part of the circuitry by applying a test signal to the tested part of the circuitry and/or storing an output of the tested part of the circuitry in accordance with one of the Boundary Scan test modes. The instruction register is arranged to store a one-hot encoded instruction identifying one of the Boundary Scan test modes. The Boundary Scan register is further arranged to extract which test to perform on the tested part of the circuitry from the one-hot encoded instruction stored in the instruction register. The integrated circuit chip and corresponding methods and hardware devices may benefit from increased test flexibility and reduced time to market.

### BACKGROUND OF THE INVENTION

1. Field of the Invention

The present invention relates generally to Boundary Scan test compatible hardware devices and corresponding methods and integrated circuit chips, and in particular to the instruction register in such Boundary Scan test compatible hardware devices.

2. Description of the Related Art

Boundary Scan testing was developed in the 1980s to address physical access problems on printed circuit boards (PCBs) caused by increasingly dense PCB assemblies due to novel packaging technologies.

Historically, most PCB testing was performed using bed of nail test equipment. Test access points were typically built into the PCBs, and probes from a bed of nails fixture could make contact with the PCBs' test pads and tests could be run on a device or cluster of devices on the PCB to locate interconnect defects such as opens or shorts.

With surface mount packaging, devices could be placed on both sides of a PCB. This made it difficult for a probe from a bed of nails fixture to hit a test access point. At the same time, PCBs migrated toward multi-layer constructions in order to accommodate the many device interconnections typically needed. Multi-layer PCBs exacerbated the problem of access to test points because physical test probes could not penetrate several layers on a PCB to test an interconnection below its surface.

However, as PCBs became more complex, the need for thorough testing became increasingly important. Therefore, in 1985 the Joint Test Action Group (JTAG) was formed to develop a methodology that could be used to test the physical interconnections of digital semiconductors without physical access by test probes. As a result, the IEEE 1149.1 test access port (TAP) and Boundary Scan standard was created in 1990. The comprehensive digital test scheme is based on additional device logic and a four wire test bus, optionally extended by a fifth reset line.

The Boundary Scan test architecture can test pin connections without using physical test probes and capture functional data while a device is operating normally. A typical design of the Boundary Scan test architecture is shown in FIG. 1. A Boundary Scan compatible chip 100 comprises core logic circuitry 115 responsible for performing the functions the chip 100 has been designed for. Primary input signals can be provided to the core logic circuitry 115 through input pins 105. Accordingly, primary output signals are conducted from the core logic circuitry 115 through output pins 125.

Boundary Scan testing requires that between the core logic circuitry 115 and each of the input/output pins 105, 125, i.e., at the periphery or “boundary” of the chip 100, a multipurpose memory element called a Boundary Scan (BS) cell 110, 120 is interposed. The Boundary Scan cells are configured as a parallel-in, parallel-out shift register: the Boundary Scan register. The Boundary Scan cells 110 (120) can force test data on the core logic circuitry 115 (the output pins 125) or capture data from input pin 105 signals (core logic 115 signals). Forced test data can be taken over into the Boundary Scan cells 110, 120 in parallel or shifted serially into the Boundary Scan register starting at a dedicated input pin of the Boundary Scan chip 100, the test data in (TDI) pin 130. Captured data is serially shifted out of the Boundary Scan register through the dedicated test data out (TDO) pin 150 and externally compared to expected results.

The Boundary Scan cells 110, 120 are implemented into the Boundary Scan chip for test purposes only. During standard operation of the core logic circuitry 115, the Boundary Scan cells 110, 120 are inactive and do not affect signal propagation through the Boundary Scan chip 100.

The type of test to be performed is determined by an instruction which can be serially shifted in and out of an instruction register 145 through the TDI and TDO pins 130, 150 respectively. Based on the instruction stored in the instruction register 145, mode control signals can be provided to the Boundary Scan cells 110, 120. For this purpose, the instruction stored in the instruction register 145 has to be decoded by a separate decoder 175.

The instruction can also specify that instead of the Boundary Scan register, test data are shifted from the TDI pin 130 to the TDO pin 150 through the bypass register 135 or the data register 140. The bypass register 135 is a one-bit data register used to provide a minimum-length serial path between the TDI and TDO pins 130, 150 to give test equipment easy access to another Boundary Scan chip that may be connected to the Boundary Scan chip 100 on the PCB. The data register 140 is an optional additional register. Typically, the data register 140 is an identification register that serves to read out an identification number which is hardwired on the Boundary Scan chip 100.

Timing and control signals for the registers 110, 120, 135, 140, 145 are provided by a test access port (TAP) controller 165, a finite state machine operating on basis of a test clock (TCK) signal provided at the TCK pin 155 and whose state transitions are controlled by a test mode select (TMS) signal applied through the TMS pin 160. Optionally, a test reset (TRST) signal can be provided to the TAP controller 165 over the TRST pin 170.

The TDI, TDO, TCK and TMS signal lines build up the four wire TAP bus defined in the IEEE 1149.1 standard. If the optional TRST signal line is implemented, it is usually also comprised in the TAP bus.

Boundary Scan testing can support quality assurance of a product throughout the product's entire life cycle, from debugging and validation in the development phase over production testing to failure analysis during field service. However, the design of the instruction register 145 often allows only a limited predefined set of instructions to be loaded and thus does not provide the flexibility required for optimizing quality support in the different life cycle phases of a product. In the development phase, this leads to an increased time to market which reduces the manufacturer's competitiveness and increases product costs. During production, the lack of flexibility causes a number of faults to remain undetected. The resulting loss through waste again negatively affects the product costs. During field service, the same effect decreases customer satisfaction.

Further, instructions to be loaded into the instruction register 145 are often encoded in accordance with a coding algorithm that allows to minimize the number of bit storage units required for the instruction register 145. This usually leads to a need for a complex decoder 175 to decode the accordingly encoded instructions. Thus, many conventional Boundary Scan devices have the disadvantage of high hardware complexity and thus increased manufacturing costs.

Moreover, conventional Boundary Scan compatible devices often suffer from the problem that the generation of the mode control signals controlling operation of the Boundary Scan cells 110, 120 from the instruction stored in the instruction register 145 through the decoder 145 is error-prone due to an inefficient bit representation in which the instruction has to be stored in the instruction register 145. As a result, some defective devices are erroneously identified as intact and vice versa. This further negatively impacts customer satisfaction as well as product costs and thus the overall competitiveness of the manufacturer.

### SUMMARY OF THE INVENTION

Improved Boundary Scan compliant hardware devices and corresponding methods and integrated circuit chips are provided that may overcome the disadvantages of the conventional approaches. In particular, embodiments may increase the flexibility of Boundary Scan testing. Other embodiments may reduce the Boundary Scan test error rate. Further embodiments may allow for reducing implementation complexity and manufacturing costs.

In one embodiment, an integrated circuit chip operable in a plurality of Boundary Scan test modes in which at least a part of the circuitry comprised in the integrated circuit chip is tested is provided. The integrated circuit chip comprises a Boundary Scan register and an instruction register. The Boundary Scan register is arranged to perform a test on the tested part of the circuitry by applying a test signal to the tested part of the circuitry and/or storing an output of the tested part of the circuitry in accorcance with one of the Boundary Scan test modes. The instruction register is arranged to store a one-hot encoded instruction identifying one of the Boundary Scan test modes. The Boundary Scan register is further arranged to extract which test to perform on the tested part of the circuitry from the one-hot encoded instruction stored in the instruction register.

In another embodiment, a method of Boundary Scan testing at least a part of the circuitry of an integrated circuit chip is provided. Thereby, the integrated circuit chip is operated in one of a plurality of Boundary Scan test modes to test the at least part of the circuitry. A one-hot encoded instruction identifying one of the Boundary Scan test modes is stored in an instruction register of the integrated circuit chip. A test is performed on the tested part of the circuitry by the Boundary Scan register by applying a test signal to the tested part of the circuitry and/or storing an output of the tested part of the circuitry in accordance with one of the Boundary Scan test modes. The Boundary Scan register extracts which test to perform on the tested part of the circuitry from the one-hot encoded instruction stored in the instruction register.

In a further embodiment, a hardware device arranged to perform a Boundary Scan test on at least part of its circuitry is provided. The hardware device comprises an integrated circuit chip operable in a plurality of Boundary Scan test modes in which at least a part of the circuitry comprised in the integrated circuit chip is tested. The integrated circuit chip comprises a Boundary Scan register and an instruction register. The Boundary Scan register is arranged to perform a test on the tested part of the circuitry by applying a test signal to the tested part of the circuitry and/or storing an output of the tested part of the circuitry in accordance with one of the Boundary Scan test modes. The instruction register is arranged to store a one-hot encoded instruction identifying one of the Boundary Scan test modes. The Boundary Scan register is further arranged to extract which test to perform on the tested part of the circuitry from the one-hot encoded instruction stored in the instruction register.

### BRIEF DESCRIPTION OF THE DRAWINGS

The accompanying drawings are incorporated into and form a part of the specification for the purpose of explaining the principles of the invention. The drawings are not to be construed as limiting the invention to only the illustrated and described examples of how the invention can be made and used. Further features and advantages will become apparent from the following and more particular description of the invention, as illustrated in the accompanying drawings, wherein:

FIG. 1 is a block diagram illustrating components of a Boundary Scan compliant chip according to prior art;

FIG. 2 is a block diagram illustrating components of a Boundary Scan compliant chip according to an embodiment;

FIG. 3 is a block diagram illustrating a Boundary Scan cell of FIG. 2 according to an embodiment;

FIG. 4 is a block diagram illustrating another Boundary Scan cell of FIG. 2 according to an embodiment;

FIG. 5 is a state transition diagram illustrating operation of the TAP controller of FIG. 2 according to an embodiment;

FIG. 6 is a block diagram illustrating components of the instruction register of FIG. 2 according to an embodiment; and

FIG. 7 is a flow diagram illustrating the process of setting a test mode according to an embodiment.

### DETAILED DESCRIPTION OF THE INVENTION

The illustrative embodiments of the present invention will be discussed with reference to the figure drawings wherein like elements and structures are indicated by like reference numbers.

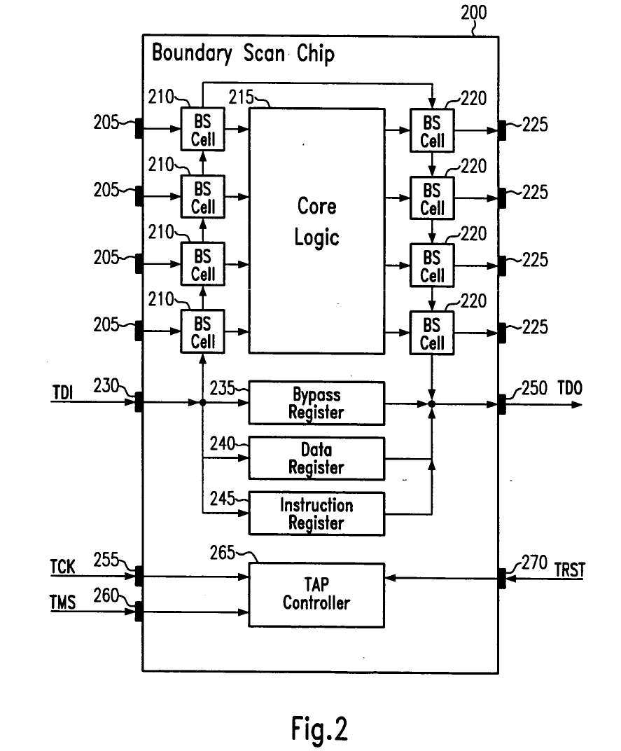

Referring now to the drawings and in particular to FIG. 2, a Boundary Scan compatible chip 200 according to an embodiment is shown. The depicted Boundary Scan chip 200 may be used in an automated test equipment (ATE) for testing the circuitry comprised in the Boundary Scan chip 200 or parts thereof. The Boundary Scan chip 200 may also be assembled with one or more other Boundary Scan chips 200 and/or other circuitry on a PCB or any other hardware device for testing (part of) its circuitry. Thereby, the output pins 225 (input pins 205) of the Boundary Scan chip 200 may be connected to the input pins (output pins) of one of the other circuits on the hardware device. In case the hardware device contains more than one Boundary Scan chip 200, the TDO pin 250 of one Boundary Scan chip 200 may be connected to the TDI pin 230 of the next Boundary Scan chip 200, thereby building up a serial Boundary Scan test chain. The TCK and TMS signals as well as the optional TRST signal may be applied in parallel to the respective TCK, TMS and TRST pins 255, 260, 270 of each Boundary Scan chip 200 on the hardware device.

The Boundary Scan chip 200 of the present embodiment may allow for performing functional (or behavioral) tests to verify that the core logic circuitry 215 of the Boundary Scan chip 200 correctly performs the behavior it was designed for. This may include testing timing and/or power consumption to verify that the core logic circuitry 215 complies with timing and/or power consumption constraints imposed thereon. Further, the Boundary Scan chip 200 may be used to perform structural tests to verify that the structure (or topology) of the manufactured Boundary Scan chip 200 is correct as specified. Moreover, the Boundary Scan chip 200 may be used for characterization tests in which critical process or performance parameters of the tested circuitry are measured under different anticipated electrical and/or environmental conditions to determine how changes in those conditions and parameters correlate.

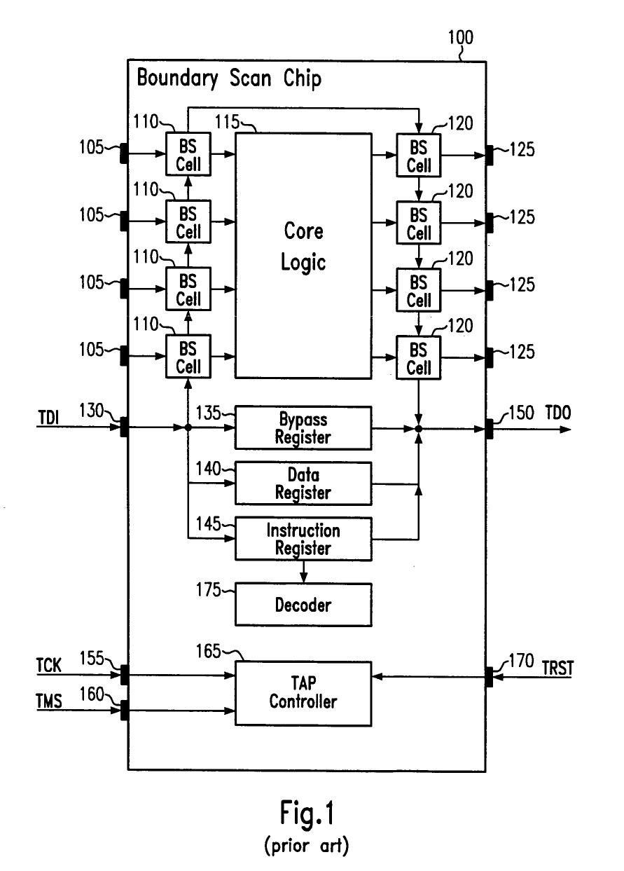

The components 205-240 and 250-270 of the Boundary Scan chip 200 may correspond to the components 105-140 and 150-170 of the Boundary Scan chip 100, respectively, described above with reference to FIG. 1.

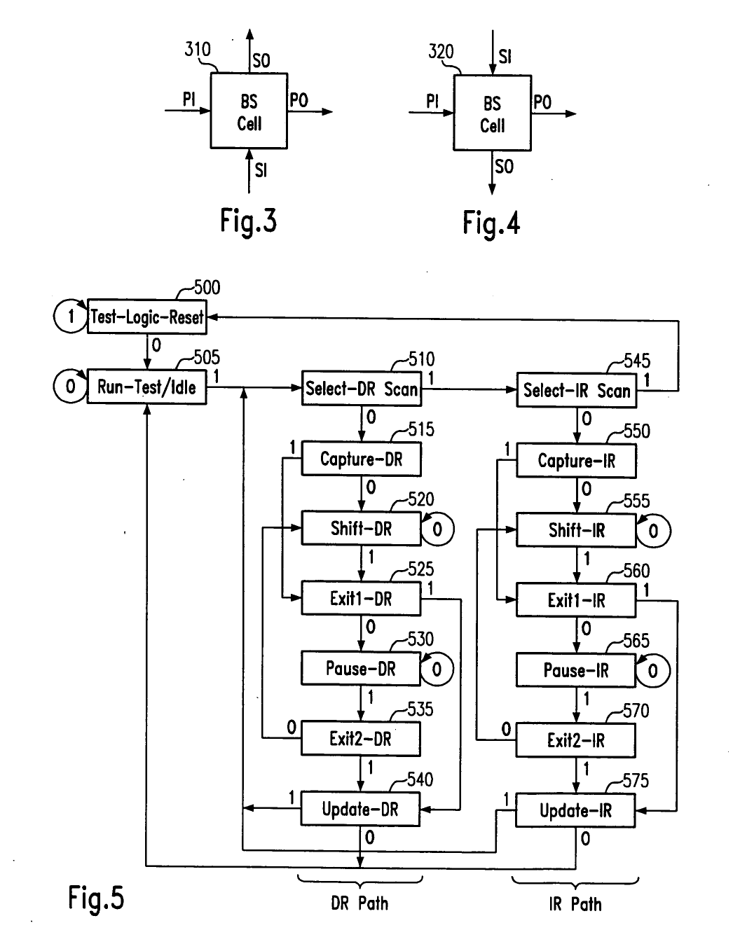

The Boundary Scan cells 210, 220 may be divided into input Boundary Scan cells 210 and output Boundary Scan cells 220. Enlarged representations of the input Boundary Scan cells 210 and output Boundary Scan cells 220 are shown in FIGS. 3 and 4, respectively. Each Boundary Scan cell may comprise a shift-in (SI) input and a shift-out (SO) output as well as a parallel-in (PI) input and a parallel-out (PO) output. The input Boundary Scan cells 210, 310 may receive input signals from the input pins 205 of the Boundary Scan chip 200 through the PI input and apply output signals to the core logic circuitry 215 through the PO output, while output Boundary Scan cells 220, 320 may receive input signals from the core logic circuitry 215 over the PI input and apply output signals to the output pins 225 of the Boundary Scan chip 200 over the PO output. Data arriving from the TDI pin 230 or the Boundary Scan cell preceding in the Boundary Scan register may be shifted into the Boundary Scan cells 210, 220, 310, 320 through the SI input and shifted out to the next Boundary Scan cell or the TDO pin 250 of the Boundary Scan chip 200 through the SO output.

It is to be noted that the number of Boundary Scan cells 210, 220 in FIG. 2 has been chosen for illustration purposes only. Alternatively, the Boundary Scan register of the Boundary Scan chip 200 may comprise any other number of Boundary Scan cells. In other embodiments, the Boundary Scan register may be comprised of input Boundary Scan cells 210 or of output Boundary Scan cells 220 only. In still other embodiments, the Boundary Scan register may also comprise enable Boundary Scan cells (not shown in FIG. 2) that, in contrast to the input and output Boundary Scan cells 210, 220, are not associated with any pin per se, but either control the direction of bi-directional pins or enable and disable certain input or output pins.

The Boundary Scan cells 210, 220, 310, 320 may be used to store measurement data, apply test data to the tested circuitry, or both, when the Boundary Scan chip 200 is operated in a Boundary Scan test mode. Further, as discussed above, the Boundary Scan cells may forward signals unmodified when the Boundary Scan chip 200 is in a normal mode of operation, thus not performing a Boundary Scan test. For this purpose, the Boundary Scan cells 210, 220, 310, 320 may comprise one or more multiplexers and one or more latches. The operation of the Boundary Scan cells 210, 220, 310, 320 may be controlled on basis of the instruction stored in the instruction register 245 as well as control signals provided by the TAP controller 265.

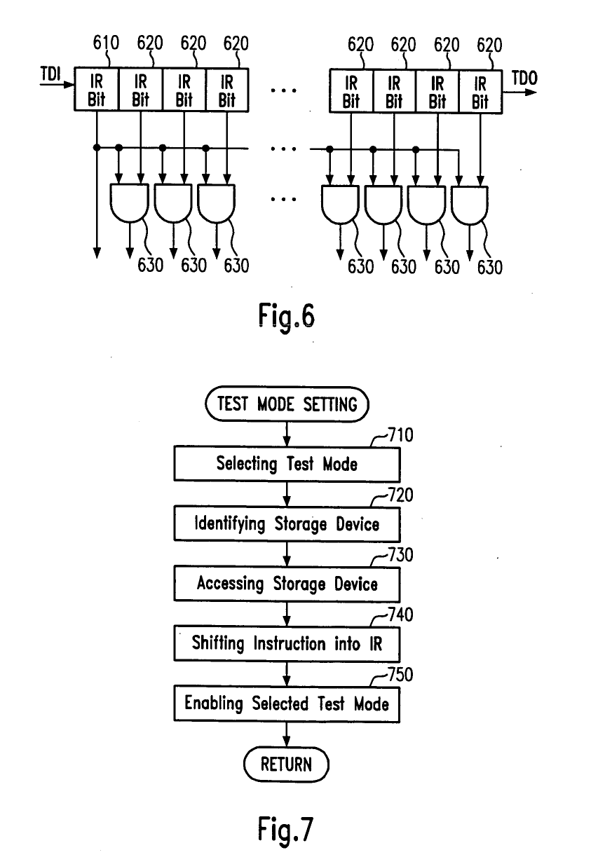

According to the present embodiment, the instruction register 245 is a one-hot encoded shift register. It will be described in more detail below with reference to FIG. 6.

Before being loaded into the instruction register 245, an instruction may be stored in another shift register (not shown in FIG. 2) accessible through the TAP interface, and in particular through the TDI and TDO signal lines. The instruction may be stored in the other shift register in the one-hot encoded format required for being loaded into the one-hot encoded instruction register 245. Therefore, no additional encoding/decoding may be required when shifting the instruction into/out of the instruction register 245.

The TAP interface may include the pins necessary to communicate to external devices through the JTAG protocol specified in the IEEE 1149.1 standard. However, according to the present embodiment, not all the instructions necessary for full JTAG compliance, i.e., compliance with the IEEE 1149.1 standard, are implemented. Therefore, the term “Boundary Scan compatibility/compliance” may be interpreted as not necessarily requiring all the instructions specified in the IEEE 1149.1 standard.

According to the present embodiment, one or more user defined instructions may be stored in one or more additional shift registers (not shown in FIG. 2) and shifted through the TAP interface into the one-hot encoded instruction register 245. Also the user defined instructions may be stored in the additional shift registers in the one-hot encoded format.

In one embodiment, the one-hot encoded instruction is directly applied to the Boundary Scan cells 210, 220 for determining the type of test to be performed. Thereby, additional decoding by a separate decoder may not be necessary, since in one-hot coding, only one bit of a digital code word is at logic high level (“1”) at a time while all the other bits of the code word are at logic low level (“0”). Thus, the one-hot encoded instruction may not be decoded by any additional, separate decoder, but the Boundary Scan cells may extract from the one-hot encoded instruction which test is to be carried out. Therefore, hardware complexity may be significantly reduced.

Further, the use of one-hot encoded instructions in the instruction register 245 may provide the advantage that the next-state logic may be simpler to define and less error-prone when performed, because only two bits may need to have their values changed.

The TAP controller 265 may provide control signals to the Boundary Scan cells 210, 220, 310, 320 which control the shift operations into the registers 210, 220, 310, 320, 235, 240, 245. The TAP controller 265 may be a finite state machine whose state transitions may be controlled by the TMS signal provided at the TMS pin 260. The timing of the TAP controller 265 may be controlled by the TCK signals provided at the TCK pin 255 independently from any other system clocks. The TCK signal may be pulsed by the equipment controlling the Boundary Scan test and not by the tested circuitry. It may be pulsed at any frequency, typically up to several MHz, even at varying rates. Further, a TRST signal may be provided to the TAP controller 265 through the TRST pin 270 for asynchronously resetting the TAP controller 265. However, the TRST signal does not necessarily have to be provided for this purpose. Alternatively, the TAP controller 265 may be reset by a certain sequence of TMS signals, e.g., by maintaining the TMS signal at the logic high level for five clock cycles of the TCK signal.

Turning now to FIG. 5, a state transition diagram of the TAP controller 265 is shown. The TAP controller 265 may have sixteen different states dedicated either to the instruction register 245 (IR) or to the Boundary Scan register 210, 220, 310, 320, bypass register 235 and optional additional data register 240, which will be referred to in the following as data registers (DR). Which one of the data registers is to be used may be selected by the instruction previously loaded into the instruction register 245. To distinguish whether data or instructions are scanned, the state transition diagram may have two separate graphs with identical structure, the DR path and the IR path. The transitions from one state to another may be controlled by the TMS signal. In FIG. 5, a transition that may be performed when the TMS signal is at the logic high level is labeled “1”, while a transition performed when the TMS signal is at the logic low level is labeled “0”.

At system startup or after a reset induced, e.g., by the TRST signal, the TAP controller 265 may be in the test logic reset state 500. In this state, all the test logic may be disabled and the normal operation of the core logic circuitry 215 may be enabled. In the run test/idle state 505, the Boundary Scan test logic may be active only if certain instructions are present. Otherwise, the Boundary Scan test logic may be idle. The select-DR scan state 510 may be a transitional state controlling whether to enter the DR path or the select-IR scan state 545. Also, the select-IR scan state 545 may be a transitional state. This state may control whether the TAP controller 265 passes the IR path or returns to the test logic reset state 500.

The capture-DR state 515 may allow data to be loaded from parallel inputs into one of the data registers selected by the previously loaded instruction. If the selected data register has no parallel inputs, the respective register may retain its state. In the shift-DR state 520, data may be shifted by one stage in the currently selected register from the TDI pin towards the TDO pin 250. The exit1-DR state 525 may be a transitional state allowing the option of passing to the pause-DR state 530 or transitioning directly to the update-DR state 540. The pause-DR state 530 may be a wait state allowing shifting of data to be temporarily halted. The exit2-DR state 535 may be a transitional state allowing the option of passing to the update-DR state 540 or returning to the shift-DR state 520 to continue accepting data. In the update-DR state 540, the data contained in the currently selected data register may be loaded into a latched parallel output for registers that have such a latch. The parallel latch may prevent changes at the parallel register output from occurring during the shifting process. The states 550-575 of the IR path may correspond to the states 515-540 of the DR path, respectively, applied to the instruction register 245.

In FIG. 6, the components of the instruction register 245 according to an embodiment are shown. The instruction register 245 may comprise a number of storage units 610, 620, each storing one bit of the instruction loaded into the instruction register 245. The number of storage units 610, 620 may be larger than the number of instructions prestored in the additional shift registers for being loaded into the instruction register 245, thus larger than the number of predetermined Boundary Scan test modes in which the Boundary Scan chip 200 may be operated. According to an embodiment, the instruction register 245 comprises 42 storage units 610, 620.

Further, the instruction register 245 may comprise a plurality of AND gates 630. One input of each of the AND gates 630 may be connected to a different one of the storage units 620. The other inputs of the AND gates 630 may be connected in parallel to the storage unit 610 connected to the TDI signal line, which according to an embodiment stores the most significant bit (MSB) of the instruction stored in the instruction register 245. The output of each of the AND gates 630 as well as the MSB storage unit 610 may be connected to separate signal lines.

Each of the signals provided at the outputs of the AND gates 630 and the MSB storage unit 610 may be assigned to either a different one of the Boundary Scan test modes in which the Boundary Scan chip 200 may be operated, or not be assigned to any Boundary Scan test mode at all. This may provide the advantage that the one-hot encoded instructions stored in the instruction register 245 can be directly used for controlling the operation of the Boundary Scan register, without requiring additional decoding of the instructions by a separate decoder.

According to an embodiment, the signal provided from the MSB storage unit 610 may correspond to a bypass mode in which the TDI signal may be routed from the TDI pin 230 to the TDO pin 250, bypassing the instruction register 245. Further, the Boundary Scan test modes to which the signals provided at the outputs of the AND gates 630 are assigned may comprise: a memory built-in self-test (BIST) mode; a continuity test mode in which a continuity test may be performed using a plurality of NAND gates comprised in the integrated circuit chip 200 and arranged in a tree architecture; an internal scan test mode in which the tested part of the circuitry may be disconnected from the pins 205, 225 for performing an internal scan test on the tested part of the circuitry; and a tristate mode in which all the pins 205, 225 may be tristated.

FIG. 7 shows a process for setting the operational state of the Boundary Scan chip 200 to one of the Boundary Scan test modes. In step 710, one of the Boundary Scan test modes may be selected. This may be accomplished, e.g., by user input or by a software program controlling the Boundary Scan test procedure. In step 720, the storage device, i.e., the shift register storing the instruction identifying the test mode selected in step 710 may be identified. Once the relevant storage device has been identified, it may be accessed in step 730. This may include, e.g., operating multiplexers to connect the identified storage device to the instruction register 245 through the TAP interface.

In step 740, the instruction may be shifted into the instruction register 245. This may be accomplished under control of the TAP controller 265 according to the state transition diagram shown in FIG. 5. Upon having shifted the instruction into the instruction register 245, the instruction may be captured into the instruction register 245. Finally, in step 750, the selected test mode may be enabled so that the corresponding Boundary Scan test is performed by the Boundary Scan chip 200. It is to be noted that no additional decoding of the instruction is performed between steps 740 and 750 by any separate decoder.

As apparent from the above description of embodiments, a one-hot encoded instruction register 245 and user-defined instructions may be implemented to add flexibility for device debug on the ATE as well as device validation in the laboratory.

The user-defined instructions may be stored in shift registers accessible through the TAP. Once a user-defined instruction is shifted in and gets captured into the instruction register 245, the selected test mode may be enabled.

The presented embodiments may be used in an on-chip test controller and allow for identification of device issues during early silicon debug and device validation. The time to market may be sped up because the debug cycle of early silicon may be reduced due to the easy access methods provided by the embodiments.

While the invention has been described with respect to the physical embodiments constructed in accordance therewith, it will be apparent to those skilled in the art that various modifications, variations and improvements of the present invention may be made in the light of the above teachings and within the purview of the appended claims without departing from the scope of the invention. In addition, those areas in which it is believed that those of ordinary skill in the art are familiar, have not been described herein in order to not unnecessarily obscure the invention described herein. Accordingly, it is to be understood that the invention is not to be limited by the specific illustrative embodiments, but only by the scope of the appended claims.

What is claimed is:

1. An integrated circuit chip operable in a plurality of Boundary Scan test modes in which at least a part of the circuitry comprised in the integrated circuit chip is tested, the integrated circuit chip comprising:
a Boundary Scan register arranged to perform a test on the tested part of the circuitry by applying a test signal to the tested part of the circuitry and/or storing an output of the tested part of the circuitry in accordance with one of the Boundary Scan test modes; and
an instruction register arranged to store a one-hot encoded instruction identifying one of the Boundary Scan test modes;
wherein the Boundary Scan register is further arranged to extract which test to perform on the tested part of the circuitry from the one-hot encoded instruction stored in the instruction register.

2. The integrated circuit chip of claim 1, further comprising a plurality of read out signal lines connected to the instruction register; and
wherein the one-hot encoded instruction stored in the instruction register is read out through the plurality of read out signal lines to control the operation of the Boundary Scan register.

3. The integrated circuit chip of claim 2, wherein the instruction register comprises:
a plurality of bit storage units comprising an MSB (Most Significant Bit) storage unit, wherein each bit storage unit stores one bit of the one-hot encoded instruction stored in the instruction register; and
at least one AND gate, wherein a first input of the at least one AND gate is connected to one of the bit storage units except the MSB storage unit, a second input of the at least one AND gate is connected to the MSB storage unit, and an output of the AND gate is connected to one of the read out signal lines.

4. The integrated circuit chip of claim 3, wherein the instruction register comprises n bit storage units and n−1 AND gates, wherein n is an integer; and
wherein the first input of each of the n−1 AND gates is connected to a different one of the n bit storage units, the first input of none of the n−1 AND gates is connected to the MSB storage unit, and the second input of each of the n−1 AND gates is connected to the MSB storage unit.

5. The integrated circuit chip of claim 3, wherein the MSB storage unit is connected to one of the read out signal lines.

6. The integrated circuit chip of claim 3, further comprising a TAP (Test Access Port) interface connected to the instruction register and comprising a TDI (Test Data In) signal line and a TDO (Test Data Out) signal line;
wherein the one-hot encoded instruction is shifted into the instruction register through the TDI signal line and shifted out of the instruction register through the TDO signal line; and
wherein the MSB storage unit is connected to the TDI signal line.

7. The integrated circuit chip of claim 1, wherein the instruction register is a one-hot encoded shift register.

8. The integrated circuit chip of claim 1, further comprising a TAP (Test Access Port) interface connected to the instruction register and comprising a TDI (Test Data In) signal line and a TDO (Test Data Out) signal line; and
wherein the one-hot encoded instruction is shifted into the instruction register through the TDI signal line and shifted out of the instruction register through the TDO signal line.

9. The integrated circuit chip of claim 8, further comprising an instruction storage register accessible through the TAP interface; and
wherein the one-hot encoded instruction is stored in the instruction storage register before being shifted into the instruction register and/or after being shifted out of the instruction register.

10. The integrated circuit chip of claim 9, further comprising at least one further instruction storage register accessible through the TAP interface;
wherein at least one further one-hot encoded instruction is stored in the at least one further instruction storage register; and
wherein the at least one further one-hot encoded instruction can be shifted into the instruction register when the one-hot encoded instruction is shifted out of the instruction register.

11. The integrated circuit chip of claim 10, wherein the one-hot encoded instruction and the at least one further one-hot encoded instruction comprise instructions causing a functional test, a structural test and/or a characterization test to be performed on the tested circuitry.

12. The integrated circuit chip of claim 10, wherein the one-hot encoded instruction and/or the at least one further one-hot encoded instruction comprises a user defined instruction.

13. The integrated circuit chip of claim 10, wherein the tested part of the circuitry comprises a memory; and
wherein one of the one-hot encoded instruction and the at least one further one-hot encoded instruction is a memory BIST (Built-In Self-Test) enable instruction causing a built-in self-test to be performed on the memory.

14. The integrated circuit chip of claim 10, further comprising a plurality of NAND (Not-AND) gates arranged in a tree architecture; and
wherein one of the one-hot encoded instruction and the at least one further one-hot encoded instruction is a NAND tree enable instruction causing a continuity test to be performed using the plurality of NAND gates.

15. The integrated circuit chip of claim 10, further comprising a plurality of pins applying input signals to the integrated circuit chip and/or conducting output signals from the integrated circuit chip;
wherein a part of the plurality of pins can be connected in parallel to the Boundary Scan register or disconnected from the Boundary Scan register; and
wherein one of the one-hot encoded instruction and the at least one further one-hot encoded instruction is an internal scan enable instruction causing the Boundary Scan register to disconnect from the part of the plurality of pins and to perform an internal scan test on the tested part of the circuitry.

16. The integrated circuit chip of claim 10, further comprising a plurality of pins applying input signals to the integrated circuit chip and/or conducting output signals from the integrated circuit chip;
wherein a part of the plurality of pins can be connected in parallel to the Boundary Scan register or disconnected from the Boundary Scan register; and
wherein one of the one-hot encoded instruction and the at least one further one-hot encoded instruction is a tristate enable instruction causing the part of the plurality of pins to be tristated.

17. The integrated circuit chip of claim 10, wherein one of the one-hot encoded instruction and the at least one further one-hot encoded instruction is a bypass instruction causing a signal applied to the instruction register through the TDI signal line to be routed to the TDO signal line, bypassing the instruction register.

18. The integrated circuit chip of claim 10, wherein the instruction register comprises n bit storage units each storing one bit of the one-hot encoded instruction stored in the instruction register; and
wherein n is an integer larger than the number of one-hot encoded instructions stored in the instruction storage register and the at least one further instruction storage register.

19. A method of Boundary Scan testing at least a part of the circuitry of an integrated circuit chip, wherein the integrated circuit chip is operated in one of a plurality of Boundary Scan test modes to test the at least part of the circuitry, the method comprising:
storing a one-hot encoded instruction identifying said one of the Boundary Scan test modes in an instruction register of the integrated circuit chip;
performing, by a Boundary Scan register, a test on the tested part of the circuitry by applying a test signal to the tested part of the circuitry and/or storing an output of the tested part of the circuitry in accordance with said one of the Boundary Scan test modes; and
extracting, by the Boundary Scan register, which test to perform on the tested part of the circuitry from the one-hot encoded instruction stored in the instruction register.

20. The method of claim 19, wherein the integrated circuit chip further comprises a plurality of read out signal lines connected to the instruction register; and
wherein the method further comprises reading out the one-hot encoded instruction stored in the instruction register through the plurality of read out signal lines.

21. The method of claim 20, wherein the instruction register comprises a plurality of bit storage units comprising an MSB (Most Significant Bit) storage unit, wherein the instruction register further comprises at least one AND gate;
wherein storing the one-hot encoded instruction in the instruction register comprises storing one bit of the one-hot encoded instruction in one of the plurality of bit storage units each; and
wherein the method further comprises:
applying the bit stored in one of the bit storage units except the MSB storage unit to a first input of the at least one AND gate;
applying the bit stored in the MSB storage unit to a second input of the at least one AND gate; and
applying a signal provided at the output of the at least one AND gate to one of the read out signal lines.

22. The method of claim 21, wherein the instruction register comprises n bit storage units and n−1 AND gates, wherein n is an integer; and
wherein the method further comprises:
applying to the first input of each of the n−1 AND gates a different one of the bits stored in the n bit storage units;
applying to the first input of none of the n−1 AND gates the bit stored in the MSB storage unit; and
applying to the second input of each of the n−1 AND gates the bit stored in the MSB storage unit.

23. The method of claim 21, further comprising applying the bit stored in the MSB storage unit to one of the read out signal lines.

24. The method of claim 21, wherein the integrated circuit chip further comprises a TAP (Test Access Port) interface connected to the instruction register and comprising a TDI (Test Data In) signal line and a TDO (Test Data Out) signal line;
wherein the method further comprises:
shifting the one-hot encoded instruction into the instruction register through the TDI signal line; and
shifting the one-hot encoded instruction out of the instruction register through the TDO signal line; and
wherein the MSB storage unit is connected to the TDI signal line.

25. The method of claim 19, wherein the instruction register is a one-hot encoded shift register.

26. The method of claim 19, wherein the integrated circuit chip further comprises a TAP (Test Access Port) interface connected to the instruction register and comprising a TDI (Test Data In) signal line and a TDO (Test Data Out) signal line; and
wherein the method further comprises:
shifting the one-hot encoded instruction into the instruction register through the TDI signal line; and
shifting the one-hot encoded instruction out of the instruction register through the TDO signal line.

27. The method of claim 26, further comprising storing the one-hot encoded instruction in an instruction storage register accessible through the TAP interface before shifting the one-hot encoded instruction into the instruction register and/or after shifting the one-hot encoded instruction out of the instruction register.

28. The method of claim 27, further comprising:
storing at least one further one-hot encoded instruction in at least one further instruction storage register accessible through the TAP interface; and
shifting the at least one further one-hot encoded instruction into the instruction register when the instruction is shifted out of the instruction register.

29. The method of claim 28, further comprising causing by the one-hot encoded instruction and/or the at least one further one-hot encoded instruction a functional test, a structural test and/or a characterization test to be performed on the tested part of the circuitry.

30. The method of claim 28, further comprising defining the one-hot encoded instruction and/or the at least one further one-hot encoded instruction by a user.

31. The method of claim 28, wherein the tested part of the circuitry comprises a memory; and
wherein the method further comprises causing by a memory BIST (Built-In Self-Test) enable instruction among the one-hot encoded instruction and/or the at least one further one-hot encoded instruction a built-in self-test to be performed on the memory.

32. The method of claim 28, wherein the integrated circuit chip further comprises a plurality of NAND (Not-AND) gates arranged in a tree architecture; and
wherein the method further comprises causing by a NAND tree enable instruction among the one-hot encoded instruction and/or the at least one further one-hot encoded instruction a continuity test to be performed using the plurality of NAND gates.

33. The method of claim 28, wherein the integrated circuit chip further comprises a plurality of pins applying input signals to the integrated circuit chip and/or conducting output signals from the integrated circuit chip;
wherein a part of the plurality of pins can be connected in parallel to the Boundary Scan register or disconnected from the Boundary Scan register; and
wherein the method further comprises causing by an internal scan enable instruction among the one-hot encoded instruction and/or the at least one further one-hot encoded instruction the Boundary Scan register to disconnect from the part of the plurality of pins and to perform an internal scan test on the tested part of the circuitry.

34. The method of claim 28, wherein the integrated circuit chip further comprises a plurality of pins applying input signals to the integrated circuit chip and/or conducting output signals from the integrated circuit chip;
wherein a part of the plurality of pins can be connected in parallel to the Boundary Scan register or disconnected from the Boundary Scan register; and
wherein the method further comprises causing by a tristate enable instruction among the one-hot encoded instruction and/or the at least one further one-hot encoded instruction the part of the plurality of pins to be tristated.

35. The method of claim 28, further comprising causing by a bypass instruction among the one-hot encoded instruction and/or the at least one further one-hot encoded instruction a signal applied to the instruction register through the TDI signal line to be routed to the TDO signal line, bypassing the instruction register.

36. The method of claim 28, wherein the instruction register comprises n bit storage units;
wherein storing the one-hot encoded instruction in the instruction register comprises storing one bit of the one-hot encoded instruction in one of the n bit storage units each; and
wherein n is an integer larger than the number of one-hot encoded instructions stored in the instruction storage register and the at least one further instruction storage register.

37. A hardware device arranged to perform a Boundary Scan test on at least part of its circuitry and comprising an integrated circuit chip operable in a plurality of Boundary Scan test modes in which at least a part of the circuitry comprised in the integrated circuit chip is tested; and
wherein the integrated circuit chip comprises:
a Boundary Scan register arranged to perform a test on the tested part of the circuitry by applying a test signal to the tested part of the circuitry and/or storing an output of the tested part of the circuitry in accordance with one of the Boundary Scan test modes; and
an instruction register arranged to store a one-hot encoded instruction identifying one of the Boundary Scan test modes;
wherein the Boundary Scan register is further arranged to extract which test to perform on the tested part of the circuitry from the one-hot encoded instruction stored in the instruction register.
